(19) United States
(12) Patent Application Publication
(10) Pub. No.: US 2016/0330846 A1
(43) Pub. Date: Nov. 10, 2016

(54) DESMEAR TREATMENT DEVICE

(71) Applicant: USHIO DENKI KABUSHIKI KAISHA, Tokyo (JP)

(72) Inventors: Noritaka TAKEZOE, Tokyo (JP); Shinichi ENDO, Tokyo (JP); Tomoyuki HABU, Tokyo (JP)

(73) Assignee: Ushio Denki Kabushiki Kaisha, Tokyo (JP)

(21) Appl. No.: 15/111,282

(22) PCT Filed: Jan. 19, 2015
(86) PCT No.: PCT/JP2015/051236

§ 371 Date: Jul. 13, 2016

(30) Foreign Application Priority Data
Jan. 20, 2014 (JP) 2014-007591

(51) Int. Cl. H05K 3/00; B08B 7/00; B08B 5/00; H05K 3/26

(52) U.S. Cl. CPC H05K 3/0055; H05K 3/26; B08B 7/0057; B08B 5/00; B08B 7/0071; H05K 2203/087; H05K 2203/1509

(57) ABSTRACT

Disclosed is a desmear treatment device that can treat a wiring board material uniformly with high treatment efficiency even when a separation distance between ultraviolet lamps adjacent to each other in a plurality of ultraviolet lamps arranged side by side is large.

According to the present invention, there is provided a desmear treatment device including: a plurality of ultraviolet lamps arranged side by side along a to-be-treated surface; a plate-shaped light transmissive window member; and a treating gas supply mechanism. The wiring board material is disposed at a position between a gas supply port and a gas discharge port of the treating gas supply mechanism, and a treating gas flows in a direction along which the plurality of ultraviolet lamps are arranged side by side and a laminar flow of the treating gas is formed in a space formed between the wiring board material and the light transmissive window member.

### TECHNICAL FIELD

The present invention relates to a desmear treatment device. More specifically, the present invention relates to a desmear treatment device used for a smear-removing (desmear) treatment in a plate-shaped wiring board material in which an insulating layer and a conductive layer are layered on each other.

### BACKGROUND ART

As a currently known method for performing a smear-removing treatment, i.e., a desmear treatment in a plate-shaped wiring board material in which an insulating layer and a conductive layer are layered on each other, may be mentioned a dry cleaning method with the use of ultraviolet rays. As a desmear treatment device for performing the treatment by this method, a desmear treatment device using ultraviolet lamps that emit vacuum ultraviolet rays, such as excimer lamps, as an ultraviolet light source has been proposed (see Patent Literature 1, for example). Such a desmear treatment device utilizes active species (specifically, ozone and oxygen radicals, for example) generated by vacuum ultraviolet rays.

One type of such a desmear treatment device has a configuration in which light from an ultraviolet lamp that emits vacuum ultraviolet rays is irradiated onto a to-be-treated surface of a wiring board material disposed under an atmosphere of a treating gas containing an oxygen gas, for example, through a light transmissive window member.

In this desmear treatment device, since ultraviolet rays from the ultraviolet lamp are emitted toward the to-be-treated surface through the light transmissive window member, the to-be-treated surface is treated by the ultraviolet rays having reached the to-be-treated surface and active species generated by the ultraviolet rays. By using a large number of ultraviolet lamps as an ultraviolet light source and arranging the large number of ultraviolet lamps side by side at regular intervals so as to obtain uniform ultraviolet distribution on the to-be-treated surface, the wiring board material can be treated uniformly with high treatment efficiency.

In desmear treatment devices, however, a reduction in the number of ultraviolet lamps used as an ultraviolet light source has been demanded in order to reduce the device manufacturing cost and treatment cost. Therefore, there has been demanded a desmear treatment device capable of uniformly treating a wiring board material with high treatment efficiency even when the number of ultraviolet lamps constituting an ultraviolet light source is small.

### CITATION LIST

### Patent Literature

Patent Literature 1: Japanese Patent Application Laid-Open No. Hei. 8-180757

### SUMMARY OF INVENTION

### Technical Problem

The present invention has been made in view of the foregoing circumstances and has as its object the provision of a desmear treatment device capable of uniformly treating a wiring board material with high treatment efficiency even when a separation distance between ultraviolet lamps adjacent to each other in a plurality of ultraviolet lamps arranged side by side is large.

### Solution to Problem

According to the present invention, there is provided a desmear treatment device including:

a plurality of ultraviolet lamps for irradiating a to-be-treated surface of a plate-shaped wiring board material with ultraviolet rays, the plate-shaped wiring board material being configured such that an insulating layer and a conductive layer are layered on each other, the ultraviolet lamps being arranged side by side along the to-be-treated surface;

a plate-shaped light transmissive window member disposed parallel to the wiring board material between the wiring board material and the plurality of ultraviolet lamps and allowing ultraviolet rays from the ultraviolet lamps to pass therethrough; and

a treating gas supply mechanism for supplying a treating gas containing an active species source for generating active species to a space formed between the wiring board material and the light transmissive window member from a gas supply port, the treating gas supply mechanism discharging the gas having flowed through the space from a gas discharge port, wherein

the wiring board material is disposed at a position between the gas supply port and the gas discharge port of the treating gas supply mechanism, and

the treating gas flows in a direction along which the plurality of ultraviolet lamps are arranged side by side and a laminar flow of the treating gas is formed in the space formed between the wiring board material and the light transmissive window member.

In the desmear treatment device of the present invention, a separation distance between the wiring board material and the light transmissive window member may preferably be not more than 1 mm, and a gas flow velocity of the treating gas flowing through the space formed between the wiring board material and the light transmissive window member may preferably be 1 to 500 mm/sec.

In the desmear treatment device of the present invention, a pressure reducing space may preferably be provided at a position between the space formed between the wiring board material and the light transmissive window member and the gas supply port.

### Advantageous Effects of Invention

According to the desmear treatment device of the present invention, the treating gas flows in the direction along which the plurality of ultraviolet lamps are arranged side by side and the laminar flow of the treating gas is formed above the to-be-treated surface of the wiring board material. Consequently, highly uniform gas flow velocity distribution of the treating gas can be obtained above the to-be-treated surface. Furthermore, the active species generated by the ultraviolet rays are moved by the flow of the treating gas toward the downstream side in the flow direction of the treating gas. As a result, even when unevenness occurs in the illuminance distribution of ultraviolet rays from the ultraviolet lamps on the to-be-treated surface due to a large separation distance between ultraviolet lamps adjacent to each other in the plurality of ultraviolet lamps, the wiring board material can be treated uniformly with high treatment efficiency.

### BRIEF DESCRIPTION OF DRAWINGS

FIG. 1 is an explanatory sectional view illustrating the cross section of an exemplary configuration of a desmear treatment device of the present invention in a direction perpendicular to the tube axis direction of ultraviolet lamps constituting the desmear treatment device.

FIG. 2 is an explanatory view illustrating an arrangement of the plurality of ultraviolet lamps constituting the desmear treatment device of FIG. 1.

### DESCRIPTION OF EMBODIMENTS

An embodiment of the present invention will be described below.

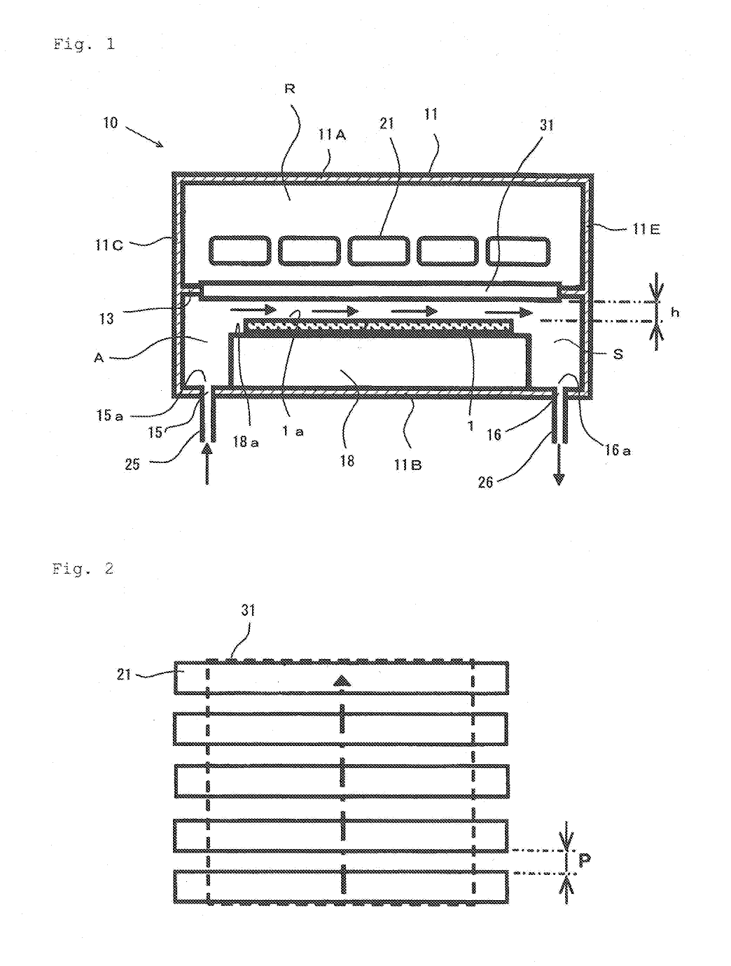

FIG. 1 is an explanatory sectional view illustrating the cross section of an exemplary configuration of a desmear treatment device of the present invention in a direction perpendicular to the tube axis direction of ultraviolet lamps constituting the desmear treatment device. FIG. 2 is an explanatory view illustrating an arrangement of the plurality of ultraviolet lamps constituting the desmear treatment device of FIG. 1.

A desmear treatment device 10 is used for treating, as a to-be-treated material, a plate-shaped wiring board material 1 in which an insulating layer and a conductive layer are layered on each other.

In the wiring board material 1, the insulating layer is constituted by a resin containing a filler made of an inorganic substance. Here, as the resin for constituting the insulating layer, may be used an epoxy resin, a bismaleimide-triazine resin, a polyimide resin and a polyester resin. Moreover, as examples of the filler material for constituting the insulating layer, may be mentioned silica, alumina, mica, silicate, barium sulfate, magnesium hydroxide and titanium oxide.

Moreover, as examples of the material for constituting the conductive layer, may be mentioned copper, nickel and gold.

In the example of this figure, the wiring board material 1 has a generally rectangular flat plate shape.

The desmear treatment device 10 includes a housing 11 having an appearance in the shape of a generally rectangular parallelepiped. Inside the housing 11, a plurality of (five in the example of this figure) rod-shaped ultraviolet lamps 21 are disposed on an upper side, and a holding device is disposed on a lower side. The holding device includes a rectangular parallelepiped to-be-treated material support 18 on which the wiring board material 1 is disposed. A light transmissive window member 31 in the shape of a rectangular flat plate is provided between the plurality of ultraviolet lamps 21 and the to-be-treated material support 18 so as to partition the internal space of the housing 11 into upper and lower parts. The light transmissive window member 31 is disposed parallel to an upper wall portion 11A and a lower wall portion 11B of the housing 11 and to a to-be-treated material placement surface 18a of the to-be-treated material support 18. In this manner, a sealed space in the shape of a generally rectangular parallelepiped, which is positioned above the light transmissive window member 31, forms a lamp chamber R, and a sealed space in the shape of a generally rectangular parallelepiped, which is positioned below the light transmissive window member 31, forms a treatment chamber S in the housing 11.

In the example of this figure, the housing 11 is provided with a window member supporting part 13 inwardly projecting along the entire perimeter of an inner periphery constituted by four side wall portions. The light transmissive window member 31 is airtightly supported by the window member supporting part 13, thus obtaining the airtight structure of the light transmissive window member 31.

In the to-be-treated material support 18, the to-be-treated material placement surface 18a has a flat surface and has a vertical and horizontal size larger than that of the wiring board material 1.

The to-be-treated material support 18 is disposed on the lower wall portion 11B of the housing 11 so as to be separated from and opposed to the light transmissive window member 31.

An effective treatment region capable of treating the wiring board material 1 with ultraviolet rays from the ultraviolet lamps 21 and active species (specifically, ozone and oxygen radicals, for example) is formed in the to-be-treated material placement surface 18a. In the wiring board material 1 disposed on the effective treatment region, a to-be-treated surface 1a is separated from and parallel to the light transmissive window member 31 and opposed to the plurality of ultraviolet lamps 21 via the light transmissive window member 31.

Moreover, the holding device is provided with a drive mechanism for driving the to-be-treated material support 18 vertically. A separation distance h between the wiring board material 1 and the light transmissive window member 31 can be adjusted by moving the to-be-treated material support 18 vertically by the drive mechanism. In other words, the desmear treatment device 10 can set the separation distance h between the wiring board material 1 and the light transmissive window member 31 to a desired size independently of the thickness of the wiring board material 1.

Here, the separation distance h between the wiring board material 1 and the light transmissive window member 31 is preferably not more than 1 mm, more preferably 0.1 to 0.7 mm.

Due to the separation distance h being not more than 1 mm, active species can be stably generated in the treatment chamber S, and ultraviolet rays having reached the to-be-treated surface 1a from the ultraviolet lamps 21 can have a sufficiently large intensity (amount of light).

In the lamp chamber R, the plurality of ultraviolet lamps 21 are arranged side by side at regular intervals along the to-be-treated material placement surface 18a so that the central axes thereof extend parallel to one another in the same horizontal plane parallel to the to-be-treated material placement surface 18a. In other words, the plurality of ultraviolet lamps 21 are disposed side by side at regular intervals along the to-be-treated surface 1a.

An interval of arranging the plurality of ultraviolet lamps 21 is preferably an equal interval.

Moreover, a separation distance between ultraviolet lamps adjacent to each other (hereinafter, it is also referred to as a “lamp-to-lamp distance”) P is preferably 5 to 50 mm.

In the example of this figure, the plurality of ultraviolet lamps 21 are disposed side by side at equal intervals.

Publicly known various lamps may be used as the ultraviolet lamp 21 according to the type of the wiring board material 1 as long as the lamp can emit vacuum ultraviolet rays with a wavelength not more than 220 nm. Specifically, as an example of the ultraviolet lamp 21, may be mentioned a xenon excimer lamp that emits vacuum ultraviolet rays with a center wavelength of 172 nm.

In the example of this figure, a rectangular excimer lamp that radiates light in a particular direction (downward direction in FIG. 1) is used as the ultraviolet lamp 21.

As the material constituting the light transmissive window member 31, may be used a material having a transmissive property for ultraviolet rays emitted from the ultraviolet lamps 21 and having resistance properties against a treating gas, the active species generated by the ultraviolet rays and a reaction product gas generated by the treatment of the to-be-treated surface 1a.

As a specific example of the material constituting the light transmissive window member 31, may be mentioned quartz glass.

Moreover, the thickness of the light transmissive window member 31 is preferably 2 to 10 mm.

The desmear treatment device 10 is provided with a gas supply mechanism for supplying a treating gas to the treatment chamber S. The gas supply mechanism can supply the treating gas to a generally rectangular space (hereinafter, it is also referred to as a “space above the to-be-treated surface”) formed between the to-be-treated surface 1a and the light transmissive window member 31 in a direction along which the plurality of ultraviolet lamps 21 are arranged side by side (in the right direction in FIG. 1, and the arrow direction of a dot-and-dash line in FIG. 2). In other words, the gas supply mechanism supplies the treating gas so that the treating gas flows generally in a linear fashion in the direction along which the plurality of ultraviolet lamps 21 are arranged side by side at least in the space above the to-be-treated surface. In the space above the to-be-treated surface, an upstream opening is formed on one side (the left side in FIG. 1) and a downstream opening is formed on the other side (the right side in FIG. 1).

The treating gas supply mechanism is provided with a treating gas supply source (not shown) and allows the treating gas to flow through the treatment chamber S via a gas supply through hole 15 and a gas discharge through hole 16 passing through the lower wall portion 11B of the housing 11. The treating gas supply source is connected to the gas supply through hole 15 via a gas flow channel forming member 25, and the gas flow channel forming member 25 forms a gas flow channel for gas supply. Moreover, a gas flow channel forming member 26 is connected to the gas discharge through hole 16, and the gas having flowed through the treatment chamber S is spontaneously discharged to a gas flow channel for gas discharge, which is formed by the gas flow channel forming member 26.

The gas supply through hole 15 includes a horizontally-long gas supply port 15a provided along a direction in which a side wall portion 11C extends (the vertical direction on the plane of paper in FIG. 1) on the inner surface of the lower wall portion 11B between the side wall portion 11C and the to-be-treated material support 18. The gas discharge through hole 16, on the other hand, includes a horizontally-long gas discharge port 16a provided along a direction in which a side wall portion 11E extends (the vertical direction on the plane of paper in FIG. 1) on the inner surface of the lower wall portion 11B between the side wall portion 11E and the to-be-treated material support 18. The gas supply port 15a and the gas discharge port 16a are formed at positions separated from each other in the surface direction (direction along which the ultraviolet lamps 21 are arranged side by side) so that the to-be-treated material support 18 is disposed therebetween. In other words, the wiring board material 1 disposed on the to-be-treated material support 18 is positioned between the gas supply port 15a and the gas discharge port 16a.

Here, each of the gas supply port 15a and the gas discharge port 16a may be formed by a single horizontally-long slit or by a plurality of holes.

In the example of this figure, the gas supply port 15a and the gas discharge port 16a are each formed by a horizontally-long slit extending along the to-be-treated material support 18.

A gas containing a source of active species, capable of generating active species by ultraviolet rays emitted from the ultraviolet lamps 21, is used as the treating gas. Here, as examples of the source of active species, may be mentioned an oxygen gas and an ozone gas.

As specific examples of the treating gas, may be mentioned an oxygen gas, and a mixture of an oxygen gas and an ozone gas. Among these, the mixture of an oxygen gas and an ozone gas is preferred from the viewpoint of shortening the treatment time. Alternatively, the treating gas may be a gas containing water vapor.

The concentration of the source of active species in the treating gas is not lower than 50% by volume, preferably not lower than 88% by volume.

When the concentration of the source of active species in the treating gas falls within the above range, the amount of active species generated by ultraviolet rays (vacuum ultraviolet rays) from the ultraviolet lamps 21 can be increased, thereby making it possible to reliably perform the desired treatment. Especially when the treating gas is the mixture of an oxygen gas and an ozone gas, a high level of safety can be achieved if the concentration of the oxygen gas is not lower than 88% by volume, i.e., if the concentration of the ozone gas is not more than 12% by volume.

Conditions for supplying the treating gas by the treating gas supply mechanism are determined so that the treating gas flowing in the space above the to-be-treated surface, i.e., flowing above the to-be-treated surface 1a has a laminar flow rectified along the to-be-treated surface 1a. In other words, the treating gas supply conditions are determined so as to form the laminar flow of the treating gas in the space above the to-be-treated surface.

Specifically, the treating gas supply conditions are appropriately determined according to the separation distance h between the wiring board material 1 and the light transmissive window member 31 as well as in consideration of the size of the to-be-treated surface 1a, the type of the ultraviolet lamp 21, and the type and composition of the treating gas, for example.

Here, when the separation distance h between the wiring board material 1 and the light transmissive window member 31 is not more than 1 mm, the gas flow velocity of the treating gas flowing through the space above the to-be-treated surface is preferably 1 to 500 mm/sec.

If the gas flow velocity in the space above the to-be-treated surface is set to 1 to 500 mm/sec as described above, the treating gas flowing through the space above the to-be-treated surface can reliably have a laminar flow.

Furthermore, in the space above the to-be-treated surface, part of active species generated in a region positioned directly below the ultraviolet lamp 21 (hereinafter, it is also referred to as a “space directly below a lamp”) can be moved to the vicinity of the space directly below a lamp by the flow of the treating gas, and can be utilized effectively for the treatment of the to-be-treated surface 1a in such a vicinity. Specifically, part of active species generated in a space directly below a lamp is moved to a region positioned directly below a gap between the ultraviolet lamps 21 adjacent to each other (hereinafter, it is also referred to as a “space directly below a gap between lamps”), which is adjacent to the space directly below a lamp. In the space directly below a gap between lamps, the active species are provided for the treatment of a region of the to-be-treated surface 1a facing the space directly below a gap between lamps.

Moreover, it is preferable that the desmear treatment device 10 includes a pressure reducing space A at a position between the space above the to-be-treated surface and the gas supply port 15a, specifically, at a position between the upstream opening of the space above the to-be-treated surface and the gas supply port 15a.

Here, the pressure reducing space A is defined to have a reservoir function of reducing the gas pressure of the treating gas introduced into the treatment chamber S from the gas supply port 15a and supplying the treating gas to the space above the to-be-treated surface at a constant pressure. The pressure reducing space A has a size facilitating the flow of the treating gas more than in the space above the to-be-treated surface.

Due to the provision of the pressure reducing space A, even when the space above the to-be-treated surface has a small thickness (the vertical dimension in FIG. 1), the treating gas can be supplied to the space above the to-be-treated surface at a constant pressure. Thus, the gas flow velocity of the treating gas in the space above the to-be-treated surface can be set to the desired range.

Moreover, it is preferable that the desmear treatment device 10 includes heating means (not shown) for heating the wiring board material 1 in the to-be-treated material support 18.

Due to the provision of the heating means, the temperature of the to-be-treated surface 1a is increased, and the action by the active species can be promoted accordingly. Thus, the treatment can be performed efficiently.

Moreover, since the vertical and horizontal size of the to-be-treated material placement surface 18a is larger than that of the wiring board material 1 in the to-be-treated material support 18, the to-be-treated surface 1a can be heated uniformly.

A heating condition by the heating means is a condition such that the temperature of the to-be-treated material placement surface 18a is 100 to 150° C., for example.

Moreover, it is preferable that the desmear treatment device 10 includes inert gas purging means (not shown) for purging an inert gas such as a nitrogen gas, for example, in the lamp chamber R.

Due to the provision of the inert gas purging means, ultraviolet rays (vacuum ultraviolet rays) from the ultraviolet lamps 21 can be outputted from the light transmissive window member 31 with high efficiency. In other words, in the lamp chamber R, the ultraviolet rays from the ultraviolet lamps 21 can be prevented from being absorbed by the gas constituting the atmosphere of the lamp chamber R.

In the thus constructed desmear treatment device 10, the surface treatment of the wiring board material 1 is performed by irradiating the to-be-treated surface 1a of the wiring board material 1 disposed under the atmosphere of the treating gas with ultraviolet rays from the ultraviolet lamps 21 through the light transmissive window member 31.

Specifically, the treating gas (specifically, an oxygen gas) is supplied to the treatment chamber S in which the wiring board material 1 is disposed from the gas supply port 15a under the desired gas supply conditions. In this manner, the treating gas is continuously supplied to the treatment chamber S, thereby causing the treatment chamber S to be under the treating gas atmosphere. Thereafter, the plurality of ultraviolet lamps 21, which are disposed side by side in the lamp chamber R, are simultaneously lit, so that ultraviolet rays are emitted from the plurality of ultraviolet lamps 21 toward the to-be-treated surface 1a through the light transmissive window member 31. Consequently, the treatment of the to-be-treated surface 1a is performed by the ultraviolet rays having reached the to-be-treated surface 1a and the active species (specifically, ozone and oxygen radicals) generated by the ultraviolet rays. Moreover, in the treatment chamber S, a reaction product gas (specifically, a carbon dioxide gas, for example) generated by the treatment of the to-be-treated surface 1a is mixed into the treating gas supplied from the gas supply port 15a during process in which the treating gas flows through the treatment chamber S. The gas into which the reaction product gas is mixed is then discharged to the outside of the treatment chamber S from the gas discharge port 16a.

In FIG. 1, the gas flow direction in the desmear treatment device 10 is indicated by arrows.

In the desmear treatment device 10, the treating gas flows in the direction along which the plurality of ultraviolet lamps 21 are arranged side by side and the laminar flow of the treating gas is formed in the space above the to-be-treated surface. Thus, the gas flow velocity distribution of the treating gas can have a high degree of uniformity in the space above the to-be-treated surface. Furthermore, the active species generated by the ultraviolet rays are moved by the flow of the treating gas toward the downstream side in the flow direction of the treating gas, i.e., toward one direction perpendicular to the tube axes of the ultraviolet lamps 21. Consequently, even if unevenness occurs in the illuminance distribution of ultraviolet rays from the ultraviolet lamps 21 on the to-be-treated surface 1a due to a large lamp-to-lamp spacing P, treatment efficiency in a region facing the space directly below a lamp, where the illuminance of ultraviolet rays is large, is prevented from being different from treatment efficiency in a region facing the space directly below a gap between lamps, where the illuminance of ultraviolet rays is small. In other words, the to-be-treated surface 1a can be treated efficiently in a short amount of time.

Specifically, in the desmear treatment device 10, when unevenness occurs in the illuminance distribution of ultraviolet rays on the to-be-treated surface 1a due to the large lamp-to-lamp spacing P, the irradiance level of ultraviolet rays having reached the region facing the space directly below a gap between lamps obviously becomes smaller than the irradiance level of ultraviolet rays having reached the region facing the space directly below a lamp on the to-be-treated surface 1a. Moreover, in the space above the to-be-treated surface, the amount of active species generated in the space directly below a gap between lamps becomes smaller than the amount of active species generated in the space directly below a lamp. Nevertheless, in the space above the to-be-treated surface, part of active species generated in a space directly below a lamp can be moved to a space directly below a gap between lamps, which is positioned downstream of the space directly below a lamp in the flow direction of the treating gas, by the flow of the treating gas having highly uniform gas flow velocity distribution. Thus, a difference in the concentration of active species can be prevented from occurring between the space directly below a lamp and the space directly below a gap between lamps, thus achieving a uniform concentration of active species in the space above the to-be-treated surface. Consequently, on the to-be-treated surface 1a, the amount of active species to be provided for the treatment of the region facing the space directly below a gap between lamps is prevented from decreasing as compared to the amount of active species to be provided for the treatment of the region facing the space directly below a lamp. Thus, the treatment of the region facing the space directly below a gap between lamps is prevented from taking a long time to perform.

Therefore, according to the desmear treatment device 10, while a large lamp-to-lamp spacing P in the plurality of ultraviolet lamps 21 reduces the irradiance level of ultraviolet rays having reached the region of the to-be-treated surface 1a facing the region directly below a gap between lamps, the amount of active species to be provided for such a region can be prevented from decreasing due to the large lamp-to-lamp spacing P. Consequently, the wiring board material 1 can be treated uniformly with high treatment efficiency.

Moreover, due to the separation distance h between the wiring board material 1 and the light transmissive window member 31 being set to be not more than 1 mm and the gas flow velocity in the space above the to-be-treated surface being set to 1 to 500 mm/sec, the laminar flow of the treating gas is formed in the space above the to-be-treated surface in the desmear treatment device 10. This allows the wiring board material 1 to be treated uniformly with higher treatment efficiency.

Specifically, since the separation distance h between the wiring board material 1 and the light transmissive window member 31 is not more than 1 mm, i.e., relatively small, ultraviolet rays having reached the to-be-treated surface 1a have a sufficiently large intensity (amount of light) and active species are stably generated in the space above the to-be-treated surface.

Moreover, since the gas flow velocity in the space above the to-be-treated surface is 1 to 500 mm/sec, i.e., relatively small, active species generated on the upstream side (the left side in FIG. 1) in the flow direction of the treating gas are not greatly moved to the downstream side (the right side in FIG. 1) in the space above the to-be-treated surface. Thus, the portion of the to-be-treated surface 1a positioned on the upstream side in the flow direction of the treating gas is sufficiently prevented from being insufficiently treated as compared to the portion of the to-be-treated surface 1a positioned on the downstream side. Furthermore, part of active species generated in a space directly below a lamp can be moved to a space directly below a gap between lamps, which is adjacent to the space directly below a lamp, so that that part can be effectively utilized for the treatment of the region of the to-be-treated surface 1a facing the space directly below a gap between lamps.

The light source device and the desmear treatment device according to the present invention are not limited to the above-described embodiment, and various modifications can be made thereto.

For example, the to-be-treated material support in the desmear treatment device may not move vertically as shown in FIG. 1.

Moreover, the desmear treatment device is not limited to the configuration in which the wiring board material is conveyed in a horizontal (lateral) position as shown in FIG. 1. The desmear treatment device may have a configuration in which the wiring board material is conveyed in a vertical (longitudinal) position.

Moreover, the desmear treatment device is not limited to the configuration in which one surface of the wiring board material is irradiated with ultraviolet rays as shown in FIG. 1. The desmear treatment device may have a configuration in which both the surfaces of the wiring board material are irradiated with ultraviolet rays.

Moreover, any treating gas supply mechanism may be used as long as the mechanism can supply a treating gas so that the treating gas flows in the direction along which the plurality of ultraviolet lamps are arranged side by side and the laminar flow of the treating gas is formed in the space above the to-be-treated surface. Specifically, the gas supply port and the gas discharge port may be provided in the side wall portions opposed to each other in the desmear treatment device of FIG. 1, for example.

### EXAMPLES

While specific examples of the present invention will be described below, the present invention is not limited to these examples.

### Example 1

According to the configuration of FIG. 1, a desmear treatment device (hereinafter, it is also referred to as a “desmear treatment device (A1)”) including five ultraviolet lamps (21) was manufactured. In the desmear treatment device (A1), a treating gas flows in a direction along which the plurality of ultraviolet lamps (21) are arranged side by side, i.e., a direction perpendicular to the tube axis direction of the ultraviolet lamps (21) (hereinafter, it is also referred to as a “direction perpendicular to lamps”).

In the desmear treatment device (A1), a xenon excimer lamp having a lamp width of 70 mm and emitting vacuum ultraviolet rays with a center wavelength of 172 nm was used as the ultraviolet lamp (21). The five ultraviolet lamps (21) were disposed at equal intervals so that a lamp-to-lamp spacing (P) was 14 mm. An oxygen gas was used as a treating gas. The treating gas was supplied so that the gas flow velocity thereof in a space between a light transmissive window member (31) and a wiring board material (1) was 5 mm/sec.

First, the rectangular plate-shaped wiring board material (1) having a vertical and horizontal size of 600 mm×500 mm and formed by an insulating layer and a conductive layer layered on each other was disposed in a treatment chamber (S) of the manufactured desmear treatment device (A1) so that a separation distance (h) with the light transmissive window member (31) was 0.5 mm. Thereafter, an oxygen gas was supplied to the treatment chamber (S) from a gas supply port (15a). The laminar flow of the treating gas was then formed in the space between the wiring board material (1) and the light transmissive window member (31).

Next, after the treatment chamber (S) was put under an oxygen gas atmosphere, the wiring board material (1) was subjected to a desmear treatment by lighting the five ultraviolet lamps (21) simultaneously while continuously supplying an oxygen gas from the gas supply port (15a).

During this desmear treatment, the illuminance of a region positioned directly below the ultraviolet lamp (21) (hereinafter, it is also referred to as an “illuminance directly below a lamp”) as well as the illuminance of a region positioned directly below a gap (hereinafter, it is also referred to as a “lamp gap”) between the ultraviolet lamps (21) adjacent to each other (hereinafter, it is also referred to as an “illuminance directly below a gap between lamps”) on a light-outputting surface (the lower surface in FIG. 1) of the light transmissive window member (31) were measured. Also, an amount of time needed to treat a region of a to-be-treated surface (1a) of the wiring board material (1) positioned directly below the lamp gap was measured. The results are shown in Table 1.

### Comparative Example 1

A desmear treatment device for comparison (hereinafter, it is also referred to as a “comparative desmear treatment device (B1)”) having the same configuration as the desmear treatment device (A1) except that a treating gas flowed in a direction perpendicular to a direction along which a plurality of ultraviolet lamps (21) were arranged side by side, i.e., in the tube axis direction of the ultraviolet lamps (21) (hereinafter, it is also referred to as a “direction parallel to lamps”) was manufactured.

With the manufactured comparative desmear treatment device (B1), a desmear treatment was performed under conditions similar to those in Example 1. An illuminance directly below a lamp and an illuminance directly below a gap between lamps on a light-outputting surface of a light transmissive window member (31) were then measured. Also, an amount of time needed to treat a region of a to-be-treated surface (1a) of a wiring board material (1) positioned directly below the lamp gap was measured. The results are shown in Table 1.

### Example 2

A desmear treatment device (hereinafter, it is also referred to as a “desmear treatment device (A2)”) having the same configuration as the desmear treatment device (A1) except that a lamp-to-lamp spacing (P) was changed according to Table 1 was manufactured.

With the manufactured desmear treatment device (A2), a desmear treatment was performed under conditions similar to those in Example 1. During this desmear treatment, the laminar flow of a treating gas was formed in a space between a wiring board material (1) and a light transmissive window member (31). An illuminance directly below a lamp and an illuminance directly below a gap between lamps on a light-outputting surface of the light transmissive window member (31) were then measured. Also, an amount of time needed to treat a region of a to-be-treated surface (1a) of the wiring board material (1) positioned directly below the lamp gap was measured. The results are shown in Table 1.

### Comparative Example 2

A desmear treatment device for comparison (hereinafter, it is also referred to as a “comparative desmear treatment device (B2)”) having the same configuration as the desmear treatment device (A2) except that a treating gas flowed in the direction parallel to lamps was manufactured.

With the manufactured comparative desmear treatment device (B2), a desmear treatment was performed under conditions similar to those in Example 2. An illuminance directly below a lamp and an illuminance directly below a gap between lamps on a light-outputting surface of a light transmissive window member (31) were then measured. Also, an amount of time needed to treat a region of a to-be-treated surface (1a) of a wiring board material (1) positioned directly below the lamp gap was measured. The results are shown in Table 1.

TABLE 1

| | | | | ILLUMINANCE ON LIGHT-OUTPUTTING | | | |
|---|---|---|---|---|---|---|---|
| | | | | SURFACE OF LIGHT TRANSMISSIVE | | | |
| | | | GAS FLOW | WINDOW MEMBER | | | |
| | | | VELOCITY | ILLUMINANCE | ILLUMINANCE | FLOW | AMOUNT OF |
| | | LAMP-TO- | OF | DIRECTLY | DIRECTLY | DIRECTION | TIME NEEDED |
| | LAMP | LAMP | TREATING | BELOW | BELOW GAP | OF TREATING | FOR |
| | WIDTH | SPACING(P) | GAS | LAMP | BETWEEN LAMPS | GAS | TREATMENT |
| EXAMPLE 1 | 70 mm | 14 mm | 5 mm/sec | 160 mW/cm² | 116 mW/cm² | DIRECTION | 100 SECONDS |
| | | | | | | PERPENDICULAR | |
| | | | | | | TO LAMPS | |
| COMPAR- | 70 mm | 14 mm | 5 mm/sec | 160 mW/cm² | 116 mW/cm² | DIRECTION | 300 SECONDS |
| ATIVE | | | | | | PARALLEL | |
| EXAMPLE 1 | | | | | | TO LAMPS | |
| EXAMPLE 2 | 70 mm | 34 mm | 5 mm/sec | 150 mW/cm² | 74 mW/cm² | DIRECTION | 165 SECONDS |
| | | | | | | PERPENDICULAR | |
| | | | | | | TO LAMPS | |
| COMPAR- | 70 mm | 34 mm | 5 mm/sec | 150 mW/cm² | 74 mW/cm² | DIRECTION | 500 SECONDS |
| ATIVE | | | | | | PARALLEL | |
| EXAMPLE 2 | | | | | | TO LAMPS | |

It is clear from the results of Table 1 that the amount of time needed to treat the region of the to-be-treated surface facing the space directly below a gap between lamps can be shortened according to the desmear treatment devices of Examples 1 and 2. Moreover, although the desmear treatment device of Example 2 has the lamp-to-lamp spacing (P) larger than that in the desmear treatment device of Example 1, it is clear that the amount of time needed to treat the region facing the space directly below a gap between lamps is approximately the same as that in the desmear treatment device of Example 1.

In the desmear treatment devices of Comparative examples 1 and 2, on the other hand, the long time was needed to treat the region of the to-be-treated surface facing the space directly below a gap between lamps. Moreover, since the desmear treatment device of Comparative example 2 had the lamp-to-lamp spacing (P) larger than that in the desmear treatment device of Comparative example 1, the amount of time needed to treat the region facing the space directly below a gap between lamps was significantly longer than that in the desmear treatment device of Comparative example 1.

Therefore, it was confirmed that the desmear treatment device of the present invention can treat the wiring board material uniformly with high treatment efficiency.

### Example 3

A desmear treatment device (hereinafter, it is also referred to as a “desmear treatment device (A3)”) having the same configuration as the desmear treatment device (A1) except that the gas flow velocity of a treating gas in a space between a light transmissive window member (31) and a wiring board material (1) was set to the gas flow velocity shown in Table 2 was manufactured.

First, the plate-shaped wiring board material (1) having a vertical and horizontal size of 600 mm×500 mm and formed by an insulating layer and a conductive layer layered on each other was disposed in a treatment chamber (S) of the manufactured desmear treatment device (A3) so that a separation distance (h) with the light transmissive window member (31) was 0.5 mm. Thereafter, an oxygen gas was supplied to the treatment chamber (S) from a gas supply port (15a). The laminar flow of the treating gas was then formed in the space between the wiring board material (1) and the light transmissive window member (31).

Next, after the treatment chamber (S) was put under an oxygen gas atmosphere, the wiring board material (1) was subjected to a desmear treatment by lighting five ultraviolet lamps (21) simultaneously while continuously supplying an oxygen gas from the gas supply port (15a).

During this desmear treatment, an illuminance directly below a lamp and an illuminance directly below a gap between lamps on a light-outputting surface of the light transmissive window member (31) were measured. Also, an amount of time needed to treat a region of a to-be-treated surface (1a) of the wiring board material (1) positioned directly below the lamp gap was measured. The results are shown in Table 2.

### Comparative Example 3

A desmear treatment device for comparison (hereinafter, it is also referred to as a “comparative desmear treatment device (B3)”) having the same configuration as the desmear treatment device (A3) except that a treating gas flowed in the direction parallel to lamps was manufactured.

With the manufactured comparative desmear treatment device (B3), a desmear treatment was performed under conditions similar to those in Example 3. An illuminance directly below a lamp and an illuminance directly below a gap between lamps on a light-outputting surface of a light transmissive window member (31) were then measured. Also, an amount of time needed to treat a region of a to-be-treated surface (1a) of a wiring board material (1) positioned directly below the lamp gap was measured. The results are shown in Table 2.

### Example 4

A desmear treatment device (hereinafter, it is also referred to as a “desmear treatment device (A4)”) having the same configuration as the desmear treatment device (A3) except that a gas flow velocity in a space between a light transmissive window member (31) and a wiring board material (1) was set to the gas flow velocity shown in Table 2 was manufactured.

With the manufactured desmear treatment device (A4), a desmear treatment was performed under conditions similar to those in Example 3. During this desmear treatment, the laminar flow of a treating gas was formed in the space between the wiring board material (1) and the light transmissive window member (31). An illuminance directly below a lamp and an illuminance directly below a gap between lamps on a light-outputting surface of the light transmissive window member (31) were then measured. Also, an amount of time needed to treat a region of a to-be-treated surface (1a) of the wiring board material (1) positioned directly below the lamp gap was measured. The results are shown in Table 2.

### Comparative Example 4

A desmear treatment device for comparison (hereinafter, it is also referred to as a “comparative desmear treatment device (B4)”) having the same configuration as the desmear treatment device (A4) except that a treating gas flowed in the direction parallel to lamps was manufactured.

With the manufactured comparative desmear treatment device (B4), a desmear treatment was performed under conditions similar to those in Example 4. An illuminance directly below a lamp and an illuminance directly below a gap between lamps on a light-outputting surface of a light transmissive window member (31) were then measured. Also, an amount of time needed to treat a region of a to-be-treated surface (1a) of a wiring board material (1) positioned directly below the lamp gap was measured. The results are shown in Table 2.

### Example 5

A desmear treatment device (hereinafter, it is also referred to as a “desmear treatment device (A5)”) having the same configuration as the desmear treatment device (A3) except that a gas flow velocity in a space between a light transmissive window member (31) and a wiring board material (1) was set to the gas flow velocity shown in Table 2 was manufactured.

With the manufactured desmear treatment device (A5), a desmear treatment was performed under conditions similar to those in Example 3. During this desmear treatment, the laminar flow of a treating gas was formed in the space between the wiring board material (1) and the light transmissive window member (31). An illuminance directly below a lamp and an illuminance directly below a gap between lamps on a light-outputting surface of the light transmissive window member (31) were then measured. Also, an amount of time needed to treat a region of a to-be-treated surface (1a) of the wiring board material (1) positioned directly below the lamp gap was measured. The results are shown in Table 2.

### Comparative Example 5

A desmear treatment device for comparison (hereinafter, it is also referred to as a “comparative desmear treatment device (B5)”) having the same configuration as the desmear treatment device (A5) except that a treating gas flowed in the direction parallel to lamps was manufactured.

With the manufactured comparative desmear treatment device (B5), a desmear treatment was performed under conditions similar to those in Example 5. An illuminance directly below a lamp and an illuminance directly below a gap between lamps on a light-outputting surface of a light transmissive window member (31) were then measured. Also, an amount of time needed to treat a region of a to-be-treated surface (1a) of a wiring board material (1) positioned directly below the lamp gap was measured. The results are shown in Table 2.

### Reference Example 1

A desmear treatment device for reference (hereinafter, it is also referred to as a “reference desmear treatment device (A6)”) having the same configuration as the desmear treatment device (A3) except that a gas flow velocity in a space between a light transmissive window member (31) and a wiring board material (1) was set to the gas flow velocity shown in Table 2 was manufactured.

With the manufactured reference desmear treatment device (A6), a desmear treatment was performed under conditions similar to those in Example 3. During this desmear treatment, the turbulent flow of a treating gas was formed in the space between the wiring board material (1) and the light transmissive window member (31). An illuminance directly below a lamp and an illuminance directly below a gap between lamps on a light-outputting surface of the light transmissive window member (31) were then measured. Also, an amount of time needed to treat a region of a to-be-treated surface (1a) of the wiring board material (1) positioned directly below the lamp gap was measured. The results are shown in Table 2.

### Comparative Example 6

A desmear treatment device for comparison (hereinafter, it is also referred to as a “comparative desmear treatment device (B6)”) having the same configuration as the reference desmear treatment device (A6) except that a treating gas flowed in the direction parallel to lamps was manufactured.

With the manufactured comparative desmear treatment device (B6), a desmear treatment was performed under conditions similar to those in Reference example 1. An illuminance directly below a lamp and an illuminance directly below a gap between lamps on a light-outputting surface of a light transmissive window member (31) were then measured. Also, an amount of time needed to treat a region of a to-be-treated surface (1a) of a wiring board material (1) positioned directly below the lamp gap was measured. The results are shown in Table 2.

TABLE 2

| | | | | ILLUMINANCE ON LIGHT-OUTPUTTING | | | |
|---|---|---|---|---|---|---|---|
| | | | | SURFACE OF LIGHT TRANSMISSIVE | | | |
| | | | GAS FLOW | WINDOW MEMBER | | | |
| | | | VELOCITY | ILLUMINANCE | ILLUMINANCE | FLOW | AMOUNT OF |
| | | LAMP-TO- | OF | DIRECTLY | DIRECTLY | DIRECTION | TIME NEEDED |
| | LAMP | LAMP | TREATING | BELOW | BELOW GAP | OF TREATING | FOR |
| | WIDTH | SPACING(P) | GAS | LAMP | BETWEEN LAMPS | GAS | TREATMENT |
| EXAMPLE 3 | 70 mm | 14 mm | 1 mm/sec | 160 mW/cm² | 116 mW/cm² | DIRECTION | 150 SECONDS |
| | | | | | | PERPENDICULAR | |
| | | | | | | TO LAMPS | |
| COMPAR- | 70 mm | 14 mm | 1 mm/sec | 160 mW/cm² | 116 mW/cm² | DIRECTION | 350 SECONDS |
| ATIVE | | | | | | PARALLEL | |
| EXAMPLE 3 | | | | | | TO LAMPS | |
| EXAMPLE 4 | 70 mm | 14 mm | 100 mm/sec | 160 mW/cm² | 116 mW/cm² | DIRECTION | 80 SECONDS |
| | | | | | | PERPENDICULAR | |
| | | | | | | TO LAMPS | |
| COMPAR- | 70 mm | 14 mm | 100 mm/sec | 160 mW/cm² | 116 mW/cm² | DIRECTION | 150 SECONDS |
| ATIVE | | | | | | PARALLEL | |
| EXAMPLE 4 | | | | | | TO LAMPS | |
| EXAMPLE 5 | 70 mm | 14 mm | 500 mm/sec | 160 mW/cm² | 116 mW/cm² | DIRECTION | 75 SECONDS |
| | | | | | | PERPENDICULAR | |
| | | | | | | TO LAMPS | |
| COMPAR- | 70 mm | 14 mm | 500 mm/sec | 160 mW/cm² | 116 mW/cm² | DIRECTION | 100 SECONDS |
| ATIVE | | | | | | PARALLEL | |
| EXAMPLE 5 | | | | | | TO LAMPS | |
| REFERENCE | 70 mm | 14 mm | 1000 mm/sec | 160 mW/cm² | 116 mW/cm² | DIRECTION | 75 SECONDS |
| EXAMPLE 1 | | | | | | PERPENDICULAR | |
| | | | | | | TO LAMPS | |
| COMPAR- | 70 mm | 14 mm | 1000 mm/sec | 160 mW/cm² | 116 mW/cm² | DIRECTION | 80 SECONDS |
| ATIVE | | | | | | PARALLEL | |
| EXAMPLE 6 | | | | | | TO LAMPS | |

It is clear from the results of Table 2 that the amount of time needed to treat the region of the to-be-treated surface facing the space directly below a gap between lamps can be shortened according to the desmear treatment devices of Examples 3 to 5.

In each of the desmear treatment devices according to Comparative examples 3 to 5, on the other hand, the longer time was needed to treat the region of the to-be-treated surface facing the space directly below a gap between lamps.

Moreover, the time needed to treat the region of the to-be-treated surface facing the space directly below a gap between lamps in the desmear treatment device of Reference example 1 is not substantially different from that in the desmear treatment device of Comparative example 6 and is the same as that in the desmear treatment device of Example 5 having the gas flow velocity of the treating gas 0.5 times that in Reference example 1. Here, the reason why the time needed for the treatment in the desmear treatment device of Reference example 1 is not substantially different from that in the desmear treatment device of Comparative example 6 is that the dispersion of the active species due to the turbulent flow of the treating gas reduces a difference in treatment efficiency, which is caused by the occurrence of unevenness in illuminance distribution on the to-be-treated surface. In other words, this is because the behavior (movement) of the active species cannot be controlled by the flow direction of the treating gas in the desmear treatment device of Reference example 1.

Therefore, it was confirmed that the desmear treatment device of the present invention can treat the wiring board material uniformly with high treatment efficiency.

### Comparative Examples 7 to 11

With the desmear treatment devices (A1) to (A5) manufactured in Examples 1 to 5, desmear treatments were performed under the same conditions as those in the examples except that the gas flow velocity of the treating gas in the space between the light transmissive window member (31) and the wiring board material (1) was set to 0 mm/sec (specifically, no oxygen gas was supplied from the gas supply port (15a)) during the desmear treatments. As a result, the desmear treatment was unable to be completed in all of the desmear treatment devices. This is because no oxygen necessary to complete the desmear treatment was supplied.

### REFERENCE SIGNS LIST

1 wiring board material
1a to-be-treated surface
10 desmear treatment device
11 housing
11A upper wall portion
11B lower wall portion
11C, 11E side wall portion
13 window member supporting part
15 gas supply through hole
15a gas supply port
16 gas discharge through hole
16a gas discharge port
18 to-be-treated material support
18a to-be-treated material placement surface
21 ultraviolet lamp
25, 26 gas flow channel forming member
31 light transmissive window member
A pressure reducing space
R lamp chamber
S treatment chamber

1. A desmear treatment device comprising:
a plurality of ultraviolet lamps for irradiating a to-be-treated surface of a plate-shaped wiring board material with ultraviolet rays, the plate-shaped wiring board material being configured such that an insulating layer and a conductive layer are layered on each other, the ultraviolet lamps being arranged side by side along the to-be-treated surface;
a plate-shaped light transmissive window member disposed parallel to the wiring board material between the wiring board material and the plurality of ultraviolet lamps and allowing ultraviolet rays from the ultraviolet lamps to pass therethrough; and
a treating gas supply mechanism for supplying a treating gas containing an active species source for generating active species to a space formed between the wiring board material and the light transmissive window member from a gas supply port, the treating gas supply mechanism discharging the gas having flowed through the space from a gas discharge port, wherein
the wiring board material is disposed at a position between the gas supply port and the gas discharge port of the treating gas supply mechanism, and
the treating gas flows in a direction along which the plurality of ultraviolet lamps are arranged side by side and a laminar flow of the treating gas is formed in the space formed between the wiring board material and the light transmissive window member.

2. The desmear treatment device according to claim 1, wherein a separation distance between the wiring board material and the light transmissive window member is not more than 1 mm, and a gas flow velocity of the treating gas flowing through the space formed between the wiring board material and the light transmissive window member is 1 to 500 mm/sec.

3. The desmear treatment device according to claim 1, wherein a pressure reducing space is provided at a position between the space formed between the wiring board material and the light transmissive window member and the gas supply port.
